(19) United States
(12) Patent Application Publication
(10) Pub. No.: US 2010/0108117 A1
(43) Pub. Date: May 6, 2010

(54) THERMOELECTRIC MODULE PACKAGE AND MANUFACTURING METHOD THEREFOR

(75) Inventors: TETSUTSUGU HAMANO, Fukuroi-shi (JP); Hiroyuki Yamashita, Hamamatsu-Shi (JP); Naoshi Horiai, Hamamatsu-Shi (JP)

Correspondence Address: DICKSTEIN SHAPIRO LLP, 1633 Broadway, NEW YORK, NY, 10019, US

(73) Assignee: YAMAHA CORPORATION, Hamamatsu-Shi (JP)

(21) Appl. No.: 12/607,210

(22) Filed: Oct. 28, 2009

(30) Foreign Application Priority Data
Oct. 30, 2008 (JP) 2008-279388

(51) Int. Cl. H01L 35/20; B23K 31/02

(52) U.S. Cl. 136/241; 228/179.1

(57) ABSTRACT

A package is adapted to a thermoelectric module in which a plurality of thermoelectric elements is electrically connected in series and aligned between a lower electrode and an upper electrode and is constituted of a metal frame and a metal base which is a metal plate having good thermal conductivity composed of copper, aluminum, silver, or alloy. The metal frame is bonded onto the periphery of the metal base via a low melting point solder whose melting point is lower than that of the solder used for forming the thermoelectric module. The thermoelectric module is circumscribed by the metal frame so that the lower electrode thereof is attached onto the metal base via an insulating resin layer.

### BACKGROUND OF THE INVENTION

1. Field of the Invention

The present invention generally relates to packages holding semiconductor devices such as semiconductor lasers, and in particular to thermoelectric module packages including metal bases and metal frames joining peripheries of metal bases, in which insulating resin layers bond metal frames to thermoelectric modules for heating or cooling semiconductor devices. The present invention also relates to manufacturing methods of thermoelectric module packages.

The present application claims priority on Japanese Patent Application No. 2008-279388, the content of which is incorporated herein by reference.

2. Description of the Related Art

Various types of thermoelectric module packages and optical module packages have been developed and disclosed in various documents such as Patent Documents 1-3.
Patent Document 1: Japanese Unexamined Patent Application Publication No. H07-128550
Patent Document 2: Japanese Patent No. 3426717
Patent Document 3: Japanese Patent No. 4101181

FIGS. 8A and 8B show a package 20 including a thermoelectric module 20a and a metal base 21 composed of a copper-tungsten (CuW) material having a good thermal conductivity with a high thermal expansion coefficient approximating to that of an iron-nickel-cobalt alloy (namely, “Kovar”, a registered trademark). A silver brazing alloy 29 (melting point: 770° C.) bonds the metal base 21 to a metal frame 22 composed of an iron-nickel-cobalt alloy (i.e. Kovar) at a high temperature. This technology is disclosed in Patent Documents 1 and 2.

Patent Document 1 discloses that the thermoelectric module 20a joins to the metal base 21 of the package 20 via a solder 23a (melting point: 118-280° C.) composed of lead (Pb), tin (Sb), indium (In), and bismuth (Bi). Patent Document 3 discloses various joining materials such as a Sn—Ag solder (melting point: 221° C.) and a Sn—Zn solder (melting point: 199° C.).

Since numerous thermoelectric elements 28 linearly join together in the thermoelectric module 20a shown in FIG. 8B, pairs of lower electrodes 24 and upper electrodes 26 join to the lower and upper ends of thermoelectric elements 28. The lower electrodes 24 are formed on a ceramic substrate 23, while the upper electrodes 26 are formed on a ceramic substrate 25. The package 20 holding the thermoelectric module 20a dissipates heat from the thermoelectric elements 28 via the ceramic substrate 23 and the metal base 21 composed of a copper-tungsten (CuW) material having a thermal conductivity of 160-200 W/mK; hence, it suffers from insufficient heat dissipation.

FIGS. 9A and 9B show a package 30 holding a thermoelectric module 30a, which is bonded to a metal base 31 (composed of copper) having a good thermal conductivity of 400 W/mK substituting for the metal base 21 composed of the CuW material via a solder 33a. A silver brazing alloy 39 (melting point: 770° C.) bonds the metal base 31 to a metal frame 32 composed of an iron-nickel-cobalt alloy (i.e. “Kovar”) at a high temperature. The thermoelectric module 30 includes numerous thermoelectric elements 38 with lower and upper ends joining to lower electrodes 34 and upper electrodes 36, which are paired and formed on ceramic substrates 33 and 35.

When the silver brazing alloy 39 bonds the metal base 31 to the metal frame 32, the metal base 31 greatly bends due to a large difference between the copper's thermal expansion coefficient (or linear expansion coefficient α) of 1.68×10⁻⁶/K and the iron-nickel-cobalt's thermal expansion coefficient (or linear expansion coefficient α) ranging from 5.7×10⁻⁶/K to 6.5×10⁻⁶/K. The metal base 31 bends like the bottom of a ship with a deflection of 100 μm, for example.

### SUMMARY OF THE INVENTION

It is an object of the present invention to provide a thermoelectric module package including a metal base and a metal frame for holding a thermoelectric module, in which the metal base composed of good conductive materials such as copper, aluminum, and silver does not bend when joining to the metal frame.

The present invention is directed to a package adapted to a thermoelectric module including a plurality of thermoelectric elements sandwiched between an upper electrode and a lower electrode. The package includes a metal base constituted of a metal plate composed of copper, aluminum, silver, or alloy, a metal frame attached to the periphery of the metal base, and an insulating resin layer having good thermal conductivity, via which the thermoelectric module is attached onto the metal base and circumscribed by the metal frame. The metal frame is attached to the metal base via a solder having a melting point lower than that of a solder used for bonding the thermoelectric elements with the upper electrode and the lower electrode in the thermoelectric module.

In the above, since the package has a small thermal resistance, the metal base easily dissipates (or exhausts) heat generated by the thermoelectric elements. Since the low melting point solder is used to bond the metal base and the metal frame together, the other solder used for forming the thermoelectric elements does not melt when soldering the metal frame to the metal base.

It is possible to further incorporate a secondary metal plate composed of copper, aluminum, silver, or alloy, which is attached onto the upper electrode of the thermoelectric module via a secondary insulating resin layer having good thermal conductivity. This makes it easy to connect other components disposed on the thermoelectric module.

It is possible to form a trench or a recess in the metal plate to engage with the lower portion of the metal frame. This makes it easy to establish the positioning between the metal base and the metal frame, and this improves the joining strength between the metal base and the metal frame.

It is possible to coat the surface of the metal base is coated with metal coating layer having good corrosion resistance and good soldering wettability, preferably, a nickel plating layer or a gold plating layer deposited on the nickel plating layer. This improves the corrosion resistance of the metal base, and this makes it easy to additionally attach heat-dissipation fins onto the metal base.

Preferably, the metal frame is composed of an iron-nickel-cobalt alloy or a stainless steel alloy. Herein, it is preferable to perform the surface processing of nickel on the metal frame.

When the insulating resin layer is formed using an insulating resin sheet including fillers having good thermal conductivity, it is possible to improve the thermal conductivity of the insulating resin layer, thus making it further easy to dissipate heat from the thermoelectric elements via the metal plate. Examples of fillers include, but not limited to, alumina powder, aluminum nitride powder, magnesium oxide powder, and silicon carbide powder. Examples of insulating resin sheets include, but not limited to, polyimide resin and epoxy resin.

The present invention is also directed to a manufacturing method of the aforementioned package. Specifically, the lower electrode of the thermoelectric module is bonded onto the metal base, which is a metal plate composed of copper, aluminum, silver, or alloy, via the insulating resin layer having a good thermal conductivity; a plurality of thermoelectric elements is aligned on the lower electrode and below the upper electrode joining to a heat-resistant resin film so that the thermoelectric elements are bonded with the lower electrode and the upper electrode via a first solder; the heat-resistant resin film is extracted from the upper electrode; then, the metal frame is positioned above and bonded onto the periphery of the metal base via a second solder whose melting point is lower than a melting point of the first solder.

In another aspect of the manufacturing method, the lower electrode of the thermoelectric module is bonded onto the metal base, which is a metal plate composed of copper, aluminum, silver, or alloy, via a first insulating resin layer having good thermal conductivity; a secondary metal plate composed of copper, aluminum, silver, or alloy is bonded onto the upper electrode of the thermoelectric module via a second insulating resin layer having good thermal conductivity; a plurality of thermoelectric elements is aligned on the lower electrode and below the upper electrode joining to the second insulating resin layer so that the thermoelectric elements are bonded with the lower electrode and the upper electrode via a first solder; then, the metal frame is bonded onto the periphery of the metal base via a second solder whose melting point is lower than a melting point of the first solder.

In a further aspect of the manufacturing method, the lower electrode of the thermoelectric module joins to a lower heat-resistant resin film while the upper electrode of the thermoelectric module joins to an upper heat-resistant resin film; a plurality of thermoelectric elements is aligned on the lower electrode and below the upper electrode so that the thermoelectric elements are bonded with the lower electrode and the upper electrode via a first solder; the upper heat-resistant resin and the lower heat-resistant resin film are respectively extracted from the upper electrode and the lower electrode so as to complete the production of the thermoelectric module; the thermoelectric module is bonded onto the metal base, which is a metal plate composed of copper, aluminum, silver, or alloy, via the insulating resin layer; then, the metal frame is positioned above and bonded onto the periphery of the metal base via a second solder whose melting point is lower than a melting point of the first solder.

### BRIEF DESCRIPTION OF THE DRAWINGS

These and other objects, aspects, and embodiments of the present invention will be described in more detail with reference to the following drawings.

FIG. 1A is a plan view of a thermoelectric module package including a metal base and a metal frame according to a preferred embodiment of the present invention.

FIG. 1B is a cross-sectional view taken along line A-A in FIG. 1A.

FIG. 2A is a plan view showing a first example of the metal base.

FIG. 2B is a cross-sectional view taken along line B-B in FIG. 2A.

FIG. 3A is a plan view showing a second example of the metal base.

FIG. 3B is a cross-sectional view taken along line C-C in FIG. 3A.

FIG. 4 is a graph showing heat dissipation characteristics of thermoelectric module packages according to the preferred embodiment and the first comparative example.

FIGS. 5A to 5G are cross-sectional views showing a first manufacturing method of the thermoelectric module package.

FIGS. 6A to 6G are cross-sectional views showing a second manufacturing method of the thermoelectric module package.

FIGS. 7A to 7G are cross-sectional views showing a third manufacturing method of the thermoelectric module package.

FIG. 8A is a plan view showing a first comparative example of a thermoelectric module package including a metal frame and a metal base.

FIG. 8B is a cross-sectional view taken along line D-D in FIG. 8A.

FIG. 9A is a plan view showing a second comparative example of a thermoelectric module package including a metal frame and a copper base.

FIG. 9B is a cross-sectional view taken along line E-E in FIG. 9A.

### DESCRIPTION OF THE PREFERRED EMBODIMENT

The present invention will be described in further detail by way of examples with reference to the accompanying drawings.

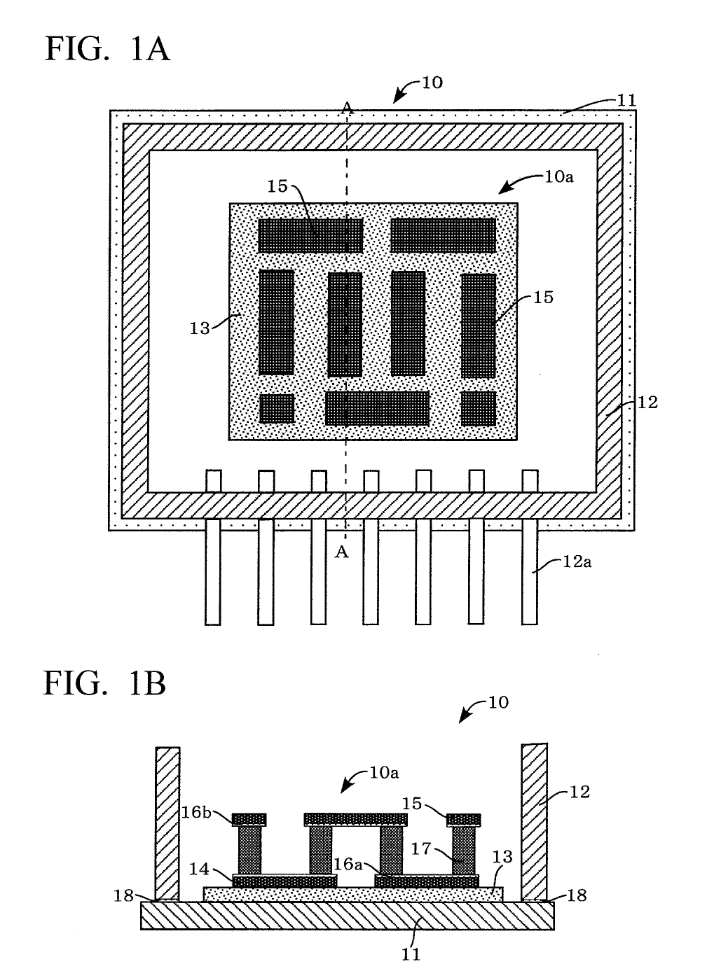

A thermoelectric module package according to a preferred embodiment of the present invention will be described with reference to FIGS. 1A and 1B, FIGS. 2A and 2B, and FIGS. 3A and 3B.

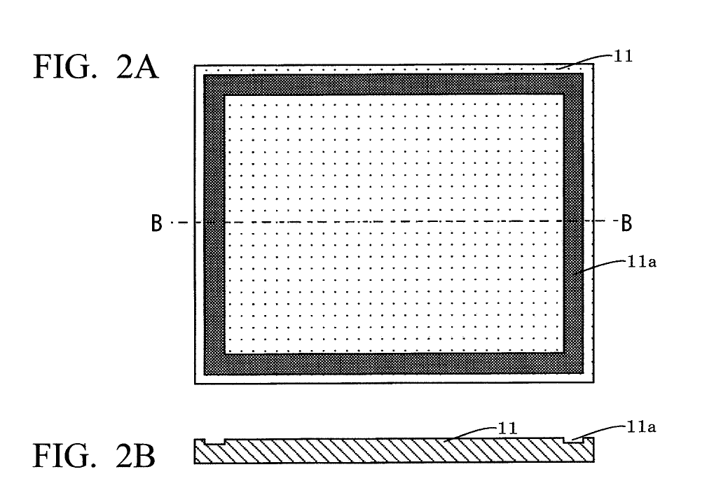

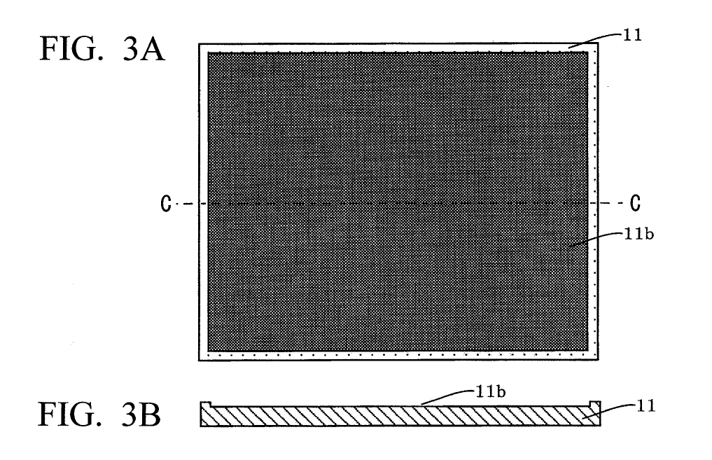

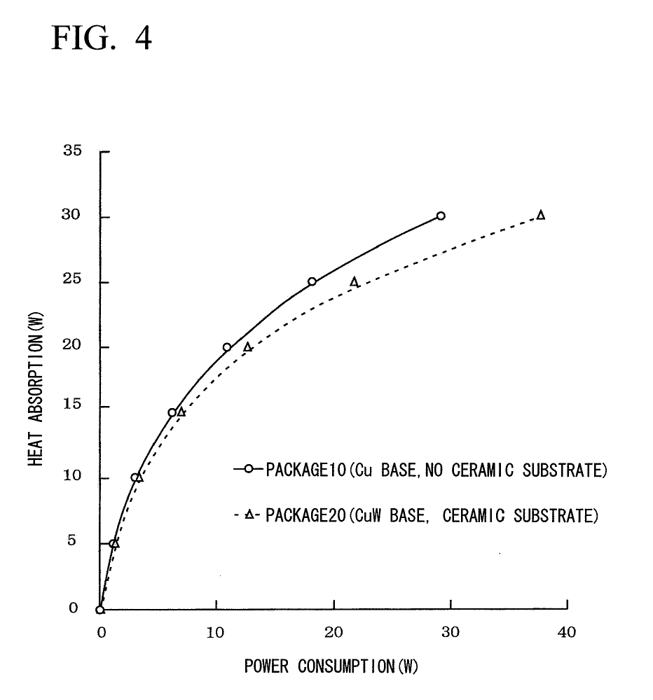

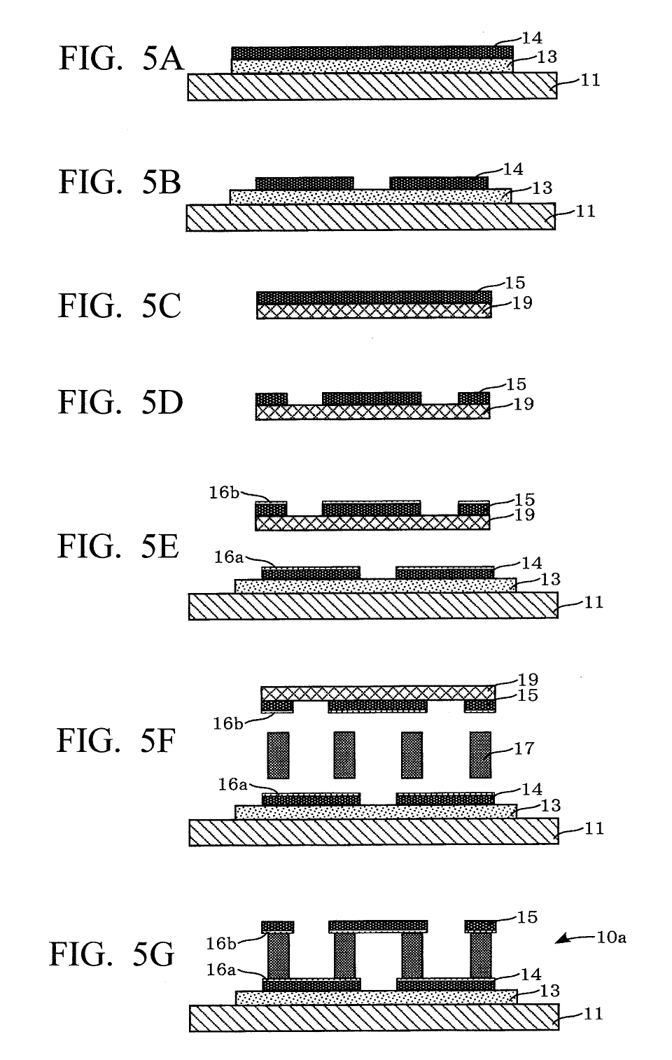

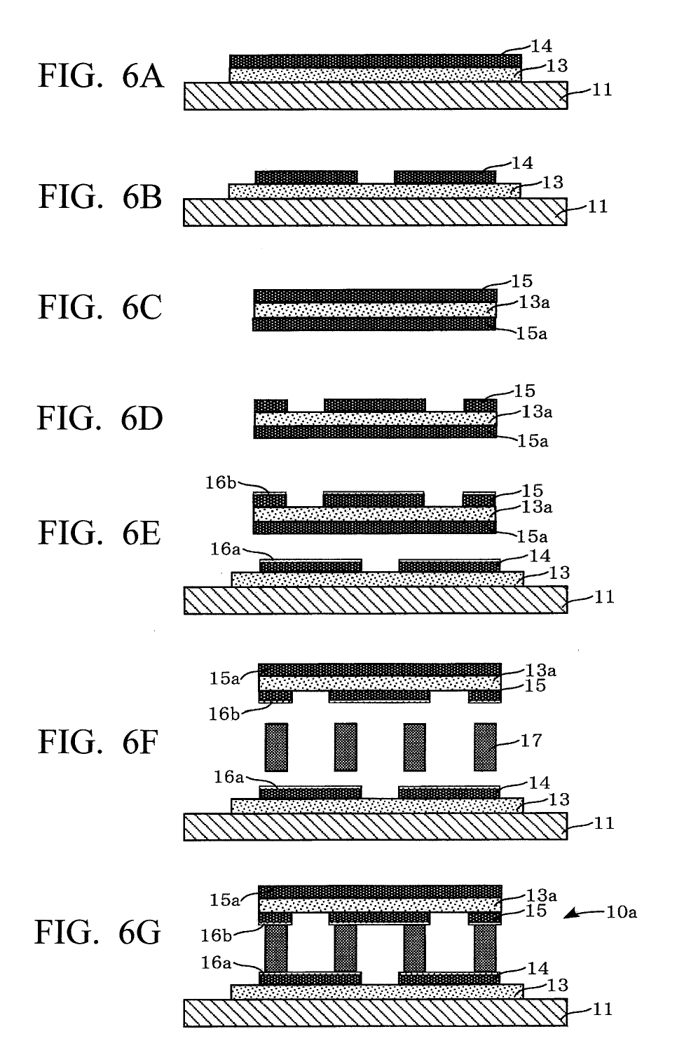

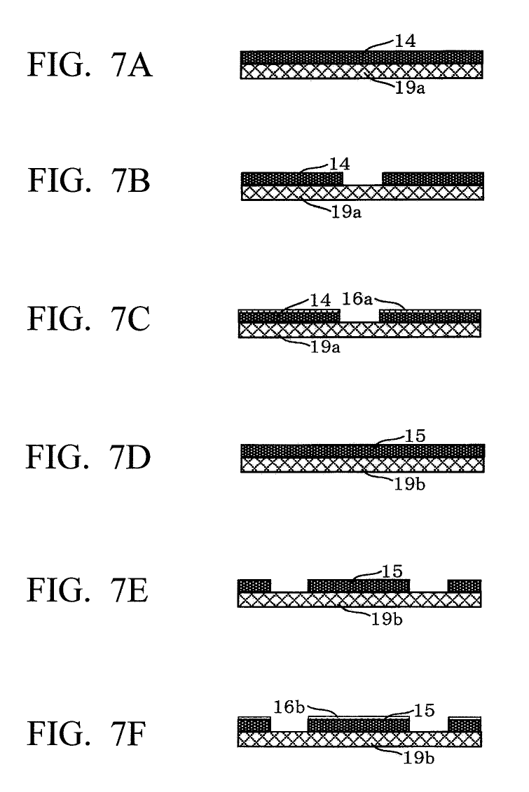

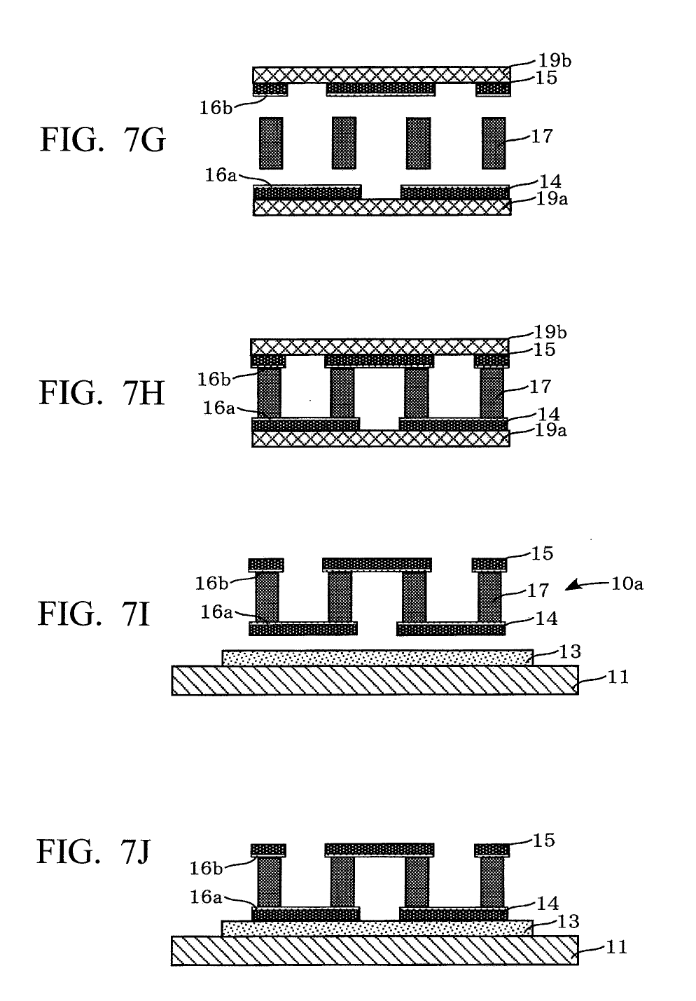

FIG. 1A is a plan view of the thermoelectric module package including a metal base and a metal frame, and FIG. 1B is a cross-sectional view taken along line A-A in FIG. 1A. FIG. 2A is a plan view showing a first example of the metal base, and FIG. 2B is a cross-sectional view taken along line B-B in FIG. 2A. FIG. 3A is a plan view showing a second example of the metal base, and FIG. 3B is a cross-sectional view taken along line C-C in FIG. 3A. FIG. 4 is a graph showing heat dissipation characteristics (i.e. the amount of heat absorption relative to the power consumption) of thermoelectric module packages according to the present embodiment and the first comparative example. FIGS. 5A to 5G are cross-sectional views showing a first manufacturing method of the thermoelectric module package; FIGS. 6A to 6G are cross-sectional views showing a second manufacturing method of the thermoelectric module package; and FIGS. 7A to 7G are cross-sectional views showing a third manufacturing method of the thermoelectric module package.

### 1. Preferred Embodiment

As shown in FIGS. 1A and 1B, a package 10 is constituted of a metal base 11 and a metal frame 12 which is bonded to the periphery of the metal base 11 via a solder 18. A thermoelectric module 10a joins to the prescribed position of the metal base 11 via an insulating resin layer 13. The thermoelectric module 10a includes a plurality of thermoelectric elements 17 which join together with pairs of lower electrodes (serving as heat-dissipation electrodes) 14 and upper electrodes (serving as heat-absorption electrodes) 15 via solders 16a and 16b.

The “adhesive” insulating resin layer 13 bonds the lower electrodes 14 to the prescribed position of the metal base 11, thus unifying the thermoelectric module 10a with the package 10. A plurality of leads joins with the upper portion of the metal frame 12 (while partially penetrating through the metal frame 12) and is connected to terminals of the thermoelectric module 10a and other terminals (not shown).

The metal base 11 is composed of a copper plate of a 400 W/mK thermal conductivity and is 1-3 mm in thickness so that the overall area thereof is 30 mm×30 mm, for example. Instead of the copper plate, it is possible to use an inexpensive copper alloy of good thermal conductivity such as bronze and brass, aluminum, and silver as well as their alloys. It is preferable that the surface of the metal base 11 be coated or plated with a metal layer having good corrosion resistance and good soldering wettability, such as a nickel plating layer and a gold plating layer (formed on the nickel plating layer).

FIGS. 2A and 2B show the first example of the metal base 11 in which a peripheral trench 11a is formed in the periphery with a depth of 0.2 mm, for example. The width of the peripheral trench 11a is approximately equal to the width of the metal frame 12 and is thus engaged with the lower portion of the metal frame 12. This improves the joining strength between the metal base 11 and the metal frame 12 and makes it easy to establish the precise positioning therebetween. Alternatively, FIGS. 3A and 3B show the second example of the metal base 11 in which a hollow portion 11b is formed with a depth of 0.2 mm except for the periphery. This also improves the joining strength between the metal base 11 and the metal frame 12 and makes it easy to establish the precise positioning therebetween.

The metal frame 12 is formed by molding an iron-nickel-cobalt alloy (preferably, the Kovar with a thermal expansion coefficient or linear expansion coefficient α ranging from 5.7×10⁻⁶/K to 6.5×10⁻⁶/K) into a rectangular frame shape.

The lower portion of the metal frame 12 is bonded to the periphery of the metal base 11 via the solder 18 such as the In solder (melting point: 156° C.), BiSn solder (melting point: is 138° C.), and SnInAg solder (melting point: 187° C.).

The solder 18 used for bonding the metal base 11 and the metal frame 12 together is low in melting point, which is lower than the melting point of the solders 16a and 16b used for forming the thermoelectric module 10a, such as the SnSb solder (melting point: 235° C.), the SnAu solder (melting point: 280° C.), and the SnAgCu solder (melting point: 220° C.). This prevents the solders 16a and 16b (used for forming the thermoelectric module 10a) from unexpectedly melting when the metal frame 12 joins to the metal base 11 via the solder 18 after the thermoelectric module 10a joins to the prescribed position of the metal base 11.

The adhesive insulating resin layer 13 is composed of an electrically insulating synthetic resin such as the polyimide resin and epoxy resin and is formed as a resin sheet with a thickness of 100 μm, for example. It is preferable to add fillers composed of alumina powder, aluminum nitride powder, magnesium oxide power, and silicon carbide power to the polyimide resin and epoxy resin, thus improving their thermal conductivity. The insulating resin layer 13 is not necessarily limited to the resin sheet but is applied to the adhesive composed of the electrically insulating synthetic resin such as the polyimide resin and epoxy resin. In this case, it is preferable to add fillers of alumina powder, aluminum nitride powder, magnesium oxide powder, and silicon carbon powder to the polyimide resin and epoxy resin, thus improving their thermal conductivity.

The lower electrode 14 and the upper electrode 15 are each composed of a copper plate with a 0.1-0.2 mm thickness and formed in prescribed electrode patterns. Herein, copper plates serving as the lower electrode 14 and the upper electrode 15 are adhered to resin sheets or heat-resistant resin films, which are then subjected to pattern etching with prescribed electrode patterns. It is possible to additionally form nickel plating layers on the lower electrodes 14 and/or the upper electrodes 15.

The thermoelectric elements 17 are composed of P-type semiconductor compounds and N-type semiconductor compounds and are each formed in prescribed dimensions (i.e. length×width×height) of 2 mm×2 mm×2 mm. Preferably, the thermoelectric elements 17 adopt thermoelectric sintered materials such as bismuth-tellurium (Bi—Te) demonstrating high performance at room temperature; P-type semiconductor compounds adopt ternary compounds of Bi—Sb—Te; and N-type semiconductor compounds adopt quartary compounds of Bi—Sb—Te—Se. Specifically, P-type semiconductor compounds have the composition of Bi_{0.5}Sb_{1.5}Te₃, and N-type semiconductor compounds have the composition of Bi_{1.9}Sb_{0.1}Te_{2.6}Se_{0.4}, wherein both compounds are formed by way of a hot-press sintering method.

It is preferable to form nickel plating layers (used for soldering) on the lower ends of the thermoelectric elements 17 (joining to the lower electrodes 14) and the upper ends of the thermoelectric elements 17 (joining to the upper electrodes 15). The thermoelectric elements 17 are electrically connected in series in the alternating order of P, N, P, N, . . . so that the lower ends and upper ends thereof are bonded to the lower electrodes 14 and the upper electrodes 15 via the solders 16a and 16b composed of the SnSb solder (melting point: 235° C.), SnAu solder (melting point: 280° C.), and SnAgCu solder (melting point: 220° C.).

As shown in FIG. 6G, it is possible to additionally arrange a metal plate 15a with a 0.1-0.2 mm thickness on the upper electrodes 15 via an insulating resin layer 13a. The metal plate 15a makes it easy to dispose various components bonded onto the thermoelectric module 10a.

### 2. First Comparative Example

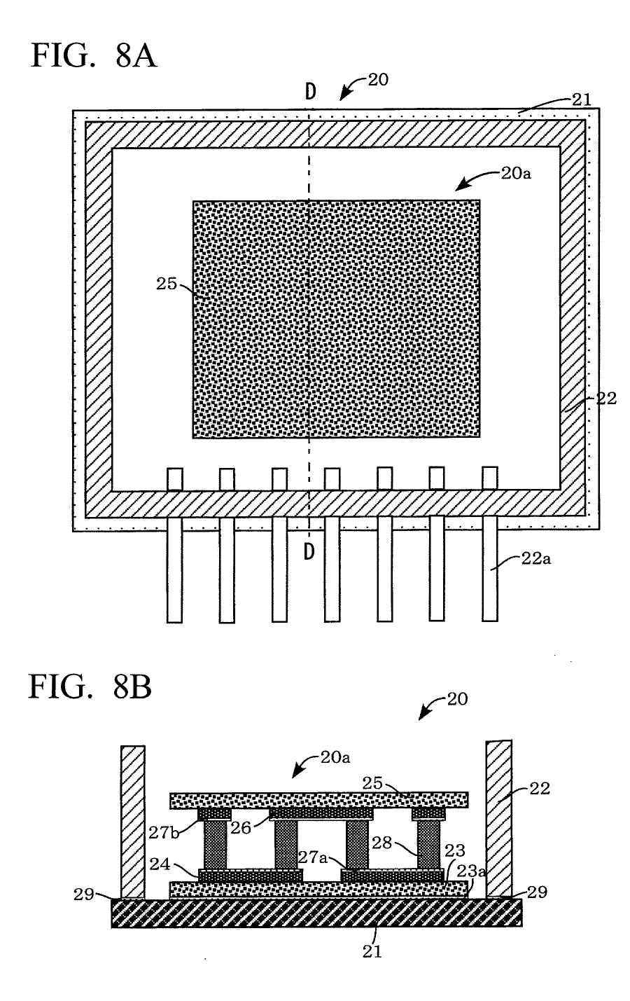

FIGS. 8A and 8B show the package 20 of the first comparative example, which is constituted of the metal base 21 composed of the CuW material, the metal frame 22 composed of the iron-nickel-cobalt alloy (Kovar) which joins to the periphery of the metal base 21 via the silver brazing alloy 29 (melting point: 770° C.), and the thermoelectric module 20a which joins to the prescribed position of the metal base 21. The thermoelectric module 20a includes a plurality of thermoelectric elements 28 that join together between the lower electrodes 24 (i.e. the heat-dissipation electrodes formed on the ceramic lower substrate 23) and the upper electrodes 26 (i.e. the heat-absorption electrodes formed on the ceramic upper substrate 25) via the solders 27a and 27b such as the SnSb solder. The first comparative example is characterized in that the thermoelectric module 20a joins to the prescribed position of the metal base 21 after the metal frame 22 joins to the metal frame 21.

Then, the solder 23a bonds the lower substrate 23 having the lower electrodes 24 to the prescribed position of the metal base 21, thus unifying the metal base 21 and the thermoelectric module 20a. The solder 23a is a low melting point solder, such as the InAg solder, SnInAg solder, and InSn solder, which is lower than the solders 27a and 27b (e.g. the SnSb solder used for bonding the thermoelectric elements 28 together) in melting point. A plurality of leads 22a running through the upper portion of the metal frame 22 are connected to terminals of the thermoelectric module 20a and other terminals (not shown).

### 3. Second Comparative Example

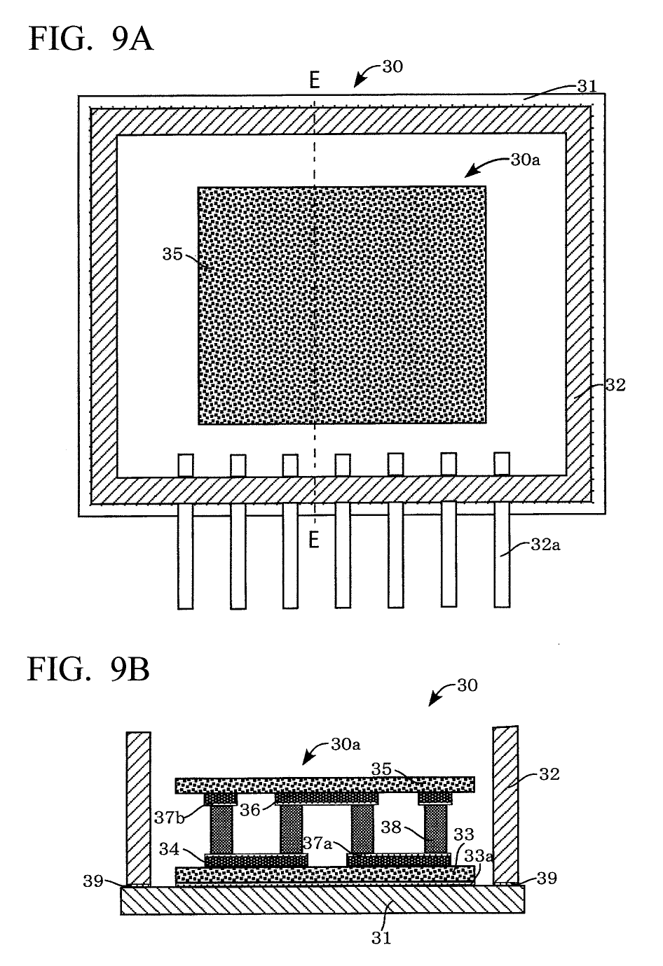

FIGS. 9A and 9B show the package 30 of the second comparative example, which is constituted of the metal base 31 (composed of a copper plate of a 400 W/mK thermal conductivity with a 1-3 mm thickness), the metal frame 32 composed of the iron-nickel-cobalt alloy (Kovar) which joins to the periphery of the metal base 31 via the silver brazing alloy (melting point: 770° C.) 39, and the thermoelectric module 30a which joins to the prescribed position of the metal base 31. The thermoelectric module 30a includes a plurality of thermoelectric elements 38 which join together between the lower electrodes 34 (i.e. the heat-dissipation electrodes formed on the ceramic lower substrate 33) and the upper electrodes 36 (i.e. the heat-absorption electrodes formed on the ceramic upper substrate 35) via the solders 37a and 37b (e.g. the SnSb solder). The second comparative example is characterized in that the thermoelectric module 30a joins to the prescribed position of the metal base 31 after the metal frame 32 joins to the metal base 31.

Then, the solder 33a bonds the lower substrate 33 having the lower electrodes 34 to the prescribed position of the metal base 31, thus unifying the thermoelectric module 30a to the metal base 31. The solder 33a is a low melting point solder, such as the InAg solder, SnInAg solder, and InSn solder, which is lower than the solders 37a and 37b (e.g. the SnSb solder used for bonding the thermoelectric elements 38 together) in melting point. A plurality of leads 32a running through the upper portion of the metal frame 32 are connected to terminals of the thermoelectric module 30a and other terminals (not shown).

### 4. Evaluation Testing

The present inventors conducted evaluation testing on the packages 10, 20, and 30 so as to measure bends (or deflections) of the metal bases 11, 21, and 31, the result of which is shown in Table 1.

TABLE 1

| | Metal | Metal | Ceramic | | Bends |
|---|---|---|---|---|---|
| Package | Base | Frame | Substrate | Joining Material | (μm) |
| 10 | Copper | Kovar | None | Solder | 25 |
| 20 | CuW | Kovar | Equipped | Silver brazing alloy | 20 |
| 30 | Copper | Kovar | Equipped | Silver brazing alloy | 100 |

Table 1 clearly shows that the package 30 (in which the silver brazing alloy 39 bonds the metal frame 32 composed of copper to the metal base 31 composed of Kovar) causes a 100 μm bend of the metal base 31, which exceeds the practical upper limit of bending of a metal base (which is empirically deduced), i.e. 50 μm; hence, the package 30 does not conform with the practical use. This is due to a large difference of thermal expansion coefficients between the copper (where α=16.8×10⁻⁶) of the metal base 31 and the Kovar (where α=5.7×10⁻⁶ through α=6.5×10⁻⁶ at 30-5000° C.) of the metal frame 32 at a certain soldering temperature.

In contrast, the package 10 (in which the solder 18 bonds the metal frame 12 composed of Kovar to the metal base 11 composed of copper) causes a 25 μm bend of the metal base 11, which is larger than a 20 μm bend occurring in the package 20 (in which the silver brazing alloy 29 bonds the metal frame 22 composed of Kovar to the metal base 21 composed of CuW (where α=6.5×10⁻⁶) by 5 μm; however, the package 10 is still suitable for the practical use. According to this result, it is preferable to solder the metal frame composed of Kovar to the metal base composed of copper.

Next, electric resistances are measured on the packages 10 and 30 in which the metal bases 11 and 31 are both composed of copper. That is, the packages 10 and 30 are repeatedly subjected to heat/cool testing by 100 cycles, wherein they are alternately subjected to a low-temperature atmosphere of −40° C. for thirty minutes and a high-temperature atmosphere of 85° C. for thirty minutes in each cycle. After heat/cool testing, electrical resistances are measured on the packages 10 and 30, and the result is shown in Table 2.

TABLE 2

| Pack- | Metal | Metal | Ceramic | Joining | Electric Resistance (Ω) | |
|---|---|---|---|---|---|---|
| age | Base | Frame | Substrate | Material | Before Test | After Test |
| 10 | Copper | Kovar | None | Solder | 2 | 2.008 |
| 30 | Copper | Kovar | Equipped | Silver | 2 | 10.125 |
| | | | | brazing | | |
| | | | | alloy | | |

Table 2 clearly shows that the package 30 (in which the thermoelectric module 30a having the lower substrate 33 joins to the metal base 31 composed of copper) suffers a very high resistance of 10.125Ω which markedly soars from the original resistance of 2Ω before testing. Visual observing the thermoelectric module 30a fixed to the package 30 indicates the occurrence of internal cracks in the thermoelectric elements 38; hence, the thermoelectric module 30a does not conform to the practical use.

In contrast, the package 10 (in which the thermoelectric module 10a having no lower substrate joins to the metal base 11 via the insulating resin layer 13 having good thermal conductivity) causes an electric resistance of 2.008Ω showing only 0.4% increase from the original resistance of 2Ω. Visually observing the thermoelectric module 10a does not indicate the occurrence of internal cracks in the thermoelectric elements 17. According to this result, it is preferable to solder the thermoelectric module having no lower substrate (or ceramic substrate) to the metal base composed of copper via the insulating resin layer having a high thermal conductivity, thus producing the package at a high reliability.

Next, the present inventors examine heat-dissipation characteristics of packages including thermoelectric modules suited to the above testing results, wherein an electric voltage is applied to the thermoelectric modules 10a and 20a held in the packages 10 and 20 so as to measure the amount of heat absorption (W) relative to the power consumption (W), thus producing a graph of FIG. 4 in which the horizontal axis represents the power consumption (W), and the vertical axis represents the heat absorption (W). Herein, each thermoelectric module is equipped with a heater (not shown) generating a prescribed amount of heat (or a prescribed amount of heat absorption) at the cooling terminal thereof, then, the thermoelectric module is electrified with an increasing current and is thus measured in the power consumption requiring the cooling terminal thereof to reach a prescribed temperature.

FIG. 4 clearly shows that the package 10 (in which the thermoelectric module 10a having no ceramic substrate joins to the metal base 11 composed of copper) requires a smaller power consumption in achieving the prescribed heat absorption in comparison with the package 20 (in which the thermoelectric module 20a having the ceramic substrate joins to the metal base 21 composed of CuW). In other words, it is preferable to bond the thermoelectric module having no ceramic substrate to the metal base composed of copper via the insulating resin layer having good thermal conductivity, thus efficiently dissipate heat from the thermoelectric elements via the metal base.

### 5. Manufacturing Methods

Next, various manufacturing methods will be described with respect to the package 10 holding the thermoelectric modules 10a by way of Examples 1 to 3.

### (1) Example 1

First, there are provided the metal base 11, the insulating resin layer 13, and the lower electrode 14 serving as the heat-dissipation electrode. The metal base 11 is constituted of a copper plate having good thermal conductivity of 400 W/mK, which is 1-3 mm in thickness, and is formed in a rectangular shape with a size of 30 mm×30 mm. The insulating resin layer 13 is constituted of a synthetic resin sheet (composed of an electrically insulating and adhesive material such as a polyimide resin and an epoxy resin) which is 100 μm in thickness, for example. The lower electrode 14 is constituted of a copper plate with a thickness of 0.1-0.2 mm.

It is preferable that the surface of the metal base 11 be covered with a metal coating layer having good corrosion resistance and good soldering wettability such as a nickel plating layer. Preferably, the insulating resin layer 13 additionally include fillers such as alumina powder, aluminum nitride powder, magnesium oxide powder, or silicon carbide powder so as to improve in thermal conductivity. It is preferable that the thermal conductivity of the insulating resin layer 13 be set to 20 W/mK or more.

As shown in FIG. 5A, the insulating resin layer 13 is laminated on the metal base 11, which is then subjected to pressurization of 0.98 MPa at a temperature of 120-160° C. for ten minutes, thus temporarily crimping the insulating resin layer 13 with the metal base 11. Next, the lower electrode 14 is laminated on the insulating resin layer 13 and is then subjected to pressurization of 2.94 MPa at a temperature of 170° C. for sixty minutes, thus bonding the metal base 11, the insulating resin layer 13, and the lower electrode 14 together to form a laminated structure. The laminated structure is subjected to masking, and the lower electrode 14 is pattern-etched to form a prescribed lower electrode pattern. This makes the lower electrode 14 have the prescribed lower electrode pattern as shown in FIG. 5B.

In the meantime, there is provided an adhesive heat-resistant resin film 19 (e.g. a product No. 360UL manufactured by Nitto Denko Corporation, and a product No. 6462 manufactured by Teraoka Seisakusho Co., Ltd.) and the upper electrode 15 serving as the heat-absorption electrode. Similar to the lower electrode 14, the upper electrode 15 is constituted of a copper plate with a thickness of 0.1-0.2 mm. As shown in FIG. 5C, the upper electrode 15 is adhered onto the surface of the heat-resistant resin film 19. The combination of the upper electrode 15 and the heat-resistant resin film 19 is subjected to masking so that the upper electrode 15 is subjected to pattern etching in a prescribed upper electrode pattern. This makes the upper electrode 15 have the prescribed upper electrode pattern as shown in FIG. 5D.

As shown in FIG. 5E, the solder 16a is applied to the lower electrode 14, while the solder 16b is applied to the upper electrode 15. Preferably, the solders 16a and 16b are composed of the SnSb solder (melting point: 235° C.), SnAu solder (melting point: 280° C.), and SnAgCu solder (melting point: 220° C.). In addition, there are provided multiple pairs of thermoelectric elements 17 composed of P-type semiconductor compounds and N-type semiconductor compounds. The thermoelectric elements 17 are each formed in a prescribed shape with prescribed dimensions (i.e. the length, width, and height) of 2 mm×2 mm×2 mm. It is preferable that nickel plating layers be formed on the lower electrode 14 (joining to the lower ends of the thermoelectric elements 17) and on the upper electrode 15 (joining to the upper ends of the thermoelectric elements 17) in order to facilitate soldering therebetween.

As shown in FIG. 5F, the thermoelectric elements 17 are aligned on the lower electrode 14 in the alternating order of P, N, P, N, . . . electrically connected in series. Then, the upper electrode 15 is positioned above the thermoelectric elements 17 to join to the upper ends of the thermoelectric elements 17. Then, the assembly is heated at a high temperature so as to melt the solders 16a and 16b, so that the thermoelectric elements 17 are soldered together with and between the lower electrode 14 and the upper electrode 15. Thereafter, the heat-resistant resin film 19 once adhered to the upper electrode 15 is peeled or extracted from the upper electrode 15 as shown in FIG. 5G, thus completely forming the thermoelectric module 10a mounted on the metal base 11 via the insulating resin layer 13.

Next, the solder 18 composed of the In solder (melting point: 156° C.), BiSn solder (melting point: 157° C.), and SnInAg solder (melting point: 180-190° C.) is applied to the periphery of the metal base 11. Subsequently, the rectangular metal frame 12 composed of an iron-nickel-cobalt alloy (preferably, the Kovar (registered trademark) having the thermal expansion coefficient (or linear expansion coefficient α) of 5.7×10⁻⁶/K through 6.5×10⁻⁶/K) is disposed on the solder 18. Then, the solder 18 is heated to melt and thereby bond the metal frame 12 onto the periphery of the metal base 11, thus completing the production of the package 10 holding the thermoelectric module 10a.

It is essential that the solder 18 used for bonding the metal base 11 and the metal frame 12 together has a low melting point solder such as the In solder (melting point: 156° C.), BiSn solder (melting point: 157° C.), and SnInAg solder (melting point: 180-190° C.), which is lower in melting point than the solders 16a and 16b used for forming the thermoelectric module 10a such as the SnSb solder (melting point: 235° C.), SnAu solder (melting point: 280° C.), and SnAgCu solder (melting point: 220° C.).

### (2) Example 2

First, there are provided the metal base 11, the “first” insulating resin layer 13, and the lower electrode 14 serving as the heat-dissipation electrode. The metal base 11 is constituted of a copper plate having a good thermal conductivity of 400 W/mK with a thickness of 1-3 mm and is formed in a prescribed size of 30 mm×30 mm. The first insulating resin 13 is constituted of a synthetic resin sheet composed of an electrically insulating and adhesive material such as a polyimide resin and epoxy resin with a thickness of 100 μm, for example. The lower electrode 14 is constituted of a copper plate with a thickness of 0.1-0.2 mm.

It is preferable that the surface of the metal base 11 be covered with a metal coating layer having good corrosion resistance and good soldering wettability such as a nickel plating layer. Preferably, the first insulating resin layer 13 additionally includes fillers such as alumina powder, aluminum nitride powder, magnesium oxide powder, and silicon carbide powder so as to improve in thermal conductivity. Preferably, the thermal conductivity of the first insulating resin layer 13 is set to 20 W/mK or more.

As shown in FIG. 6A, the first insulating resin layer 13 is laminated on the metal base 11, which is then subjected to pressurization of 0.98 MPa at a high temperature of 120-160° C. for ten minutes, thus temporarily crimping the first insulating resin layer 13 with the metal base 11. Next, the lower electrode 14 is laminated on the first insulating resin layer 13 and is then subjected to pressurization of 2.94 MPa at a high temperature of 170° C. for sixty minutes, thus forming the laminated structure including the metal base 11, the first insulating resin layer 13, and the lower electrode 14. As shown in FIG. 6B, the laminated structure is subjected to masking, and the lower electrode 14 is subjected to pattern etching and is formed in a prescribed lower electrode pattern.

In the meantime, there are provided an adhesive “second” insulating resin layer 13a and the upper electrode 15 serving as the heat-absorption electrode. Similar to the lower electrode 14, the upper electrode 15 is constituted of a copper plate with a thickness of 0.1-0.2 mm. As shown in FIG. 6C, a metal plate 15a (which is a copper plate with a thickness of 0.1-0.2 mm) is adhered onto the backside of the second insulating resin layer 13a. The second insulating resin layer 13a and the metal plate 15a are temporarily crimped together by way of the pressurization of 0.98 MPa at a high temperature of 120-160° C. for ten minutes. The upper electrode 15 is adhered onto the surface of the second insulating resin layer 13a. Then, second insulating resin layer 13a, the metal plate 15a, and the upper electrode 15 are crimped together by way of the pressurization of 2.94 MPa at a high temperature of 170° C. for sixty minutes. Thereafter, the crimped structure is subjected to masking so that the upper electrode 15 is pattern-etched to form a prescribed upper electrode pattern. FIG. 6D shows the prescribed upper electrode pattern formed in the upper electrode 15.

As shown in FIG. 6E, the solder 16a is applied to the lower electrode 14, while the solder 16b is applied to the upper electrode 15. The solders 16a and 16b are selected from the SnSb solder (melting point: 235° C.), SnAu solder (melting point: 280° C.), and SnAgCu solder (melting point: 220° C.), for example. In addition, there are provided multiple pairs of thermoelectric elements 17 serving as P-type semiconductor compounds and N-type semiconductor compounds. The thermoelectric elements 17 are each formed in a prescribed shape with prescribed dimensions (i.e. the length, width, and height) of 2 mm×2 mm×2 mm. Preferably, nickel plating layers are applied on the lower electrode 14 (joining to the lower ends of the thermoelectric elements 17) and on the upper electrode 15 (joining to the upper ends of the thermoelectric elements 17) so as to facilitate soldering therebetween.

As shown in FIG. 6F, the thermoelectric elements 17 are aligned on the lower electrode 14 in the alternating order of P, N, P, N, . . . electrically connected in series. Subsequently, the upper electrode 15 is positioned above the thermoelectric elements 17. Then, the solders 16a and 16b are heated to melt at a high temperature, so that the thermoelectric elements 17 join together between the lower electrode 14 and the upper electrode 15, and the thermoelectric module 10a is mounted on the metal base 11 via the first insulating resin layer 13. Example 2 is characterized in that the metal plate 15a (which is a copper plate with a thickness of 0.1-0.2 mm) is disposed on the upper electrode 15 via the second insulating resin layer 13a. This makes other components join onto the thermoelectric module 10a with ease.

Next, the solder 18 composed of the In solder (melting point: 156° C.), BiSn solder (melting point: 157° C.), or SiInAg solder (melting point: 180-190° C.) is applied to the periphery of the metal base 11. Subsequently, the metal frame 12 composed of an iron-nickel-cobalt alloy (preferably, the Kovar (registered trademark) having a thermal expansion coefficient (or linear expansion coefficient α) of 5.7×10⁻⁶/K through 6.5×10⁻⁶/K) is disposed on the solder 18. Then, the solder 18 is heated to melt and thereby connect the metal base 11 and the metal frame 12 together, thus completing the production of the package 10 holding the thermoelectric module 10a in which the metal plate 15a is disposed on the upper electrode 15 via the second insulating resin layer 13a.

It is preferable that the solder used for bonding the metal base 11 and the metal frame 12 together have a low melting point solder such as the In solder (melting point: 156° C.), BiSn solder (melting point: 157° C.), and SnInAg solder (melting point: 180-190° C.), which is lower in melting point than the solders 16a and 16b used for forming the thermoelectric module 10a such as the SnSb solder (melting point: 235° C.), SnAu solder (melting point: 280° C.), and SnAgCu solder (melting point: 220° C.).

### (3) Example 3

First, there are provided an adhesive heat-resistant resin film 19a (e.g. the product No. 360UL manufactured by Nitto Denko Corporation, and the product No. 6462 manufactured by Teraoka Seisakusho Co., Ltd.) and the lower electrode 14 serving as the heat-dissipation electrode. The lower electrode 14 is constituted of a copper plate with a thickness of 0.1-0.2 mm. As shown in FIG. 7A, the lower electrode 14 is adhered onto the surface of the heat-resistant resin film 19a and is then subjected to masking so that the lower electrode 14 is pattern-etched to form a prescribed lower electrode pattern. FIG. 7B shows the lower electrode 14 having the prescribed lower electrode pattern. Subsequently, the solder 16a is applied to the lower electrode 14 as shown in FIG. 7C. The solder 16a is selected from among the SnSb solder (melting point: 235° C.), SnAu solder (melting point: 280° C.), and SnAgCu solder (melting point: 220° C.), for example.

In addition, there are provided an adhesive heat-resistant resin film 19b (e.g. the product No. 360UL manufactured by Nitto Denko Corporation, and the product No. 6462 manufactured by Teraoka Seisakusho Co., Ltd.) and the upper electrode 15 serving as the heat-absorption electrode. Similar to the lower electrode 14, the upper electrode 15 is constituted of a copper plate with a thickness of 0.1-0.2 mm. As shown in FIG. 7D, the upper electrode 15 is adhered onto the surface of the heat-resistant resin film 19b and is then subjected to masking so that the upper electrode 15 is pattern-etched to form a prescribed upper electrode pattern. FIG. 7E shows the upper electrode 15 having the prescribed upper electrode pattern. Subsequently, the solder 16b is applied to the upper electrode 15 as shown in FIG. 7F. The solder 16b is selected from among the SnSb solder (melting point: 235° C.), SnAu solder (melting point: 280° C.), and SnAgCu solder (melting point: 220° C.), for example.

Next, there are provided multiple pairs of thermoelectric elements 17 composed of P-type semiconductor compounds and N-type semiconductor compounds. The thermoelectric elements 17 are each formed in a prescribed shape with prescribed dimensions (i.e. the length, width, and height) of 2 mm×2 mm×2 mm. Preferably, nickel plating layers are applied on the lower electrode 14 (joining to the lower ends of the thermoelectric elements 17) and on the upper electrode 15 (joining to the upper ends of the thermoelectric elements 17) so as to facilitate soldering therebetween. As shown in FIG. 7G, the thermoelectric elements 17 are aligned on the lower electrode 14 in the alternating order of P, N, P, N, . . . electrically connected in series. Then, the upper electrode 15 is positioned above the thermoelectric elements 17. Then, as shown in FIG. 7H, the solders 16a and 16b are heated to melt at a high temperature so as to bond the thermoelectric elements 17 together between the lower electrode 14 and the upper electrode 15. Thereafter, the heat-resistant resin film 19a once adhered to the lower electrode 14 is peeled and extracted from the lower electrode 14, and the heat-resistant resin film 19b once adhered to the upper electrode 15 is peeled and extracted from upper electrode 15, thus completing the production of the thermoelectric module 10a.

As shown in FIG. 7I, there are provided the metal base 11 and the insulating resin layer 13. The metal base 11 is constituted of a copper plate of a good thermal conductivity of 400 W/mK with a thickness of 1-3 mm and is formed in a prescribed size of 30 mm×30 mm. The insulating resin layer 13 is constituted of a synthetic resin sheet composed of an electrically insulating and adhesive material such as a polyimide resin and epoxy resin with a thickness of 100 μm, for example.

It is preferable that the surface of the metal base 11 be coated with a metal coating layer having good corrosion resistance and good soldering wettability such as a nickel plating layer. Preferably, the insulating resin layer 13 additionally includes fillers composed of alumina powder, aluminum nitride powder, magnesium oxide powder, and silicon carbide powder so as to improve in thermal conductivity. It is preferable that the thermal conductivity of the insulating resin layer 13 be set to 20 W/mK or more.

As shown in FIG. 7J, the metal base 11 is laminated with the insulating resin layer 13 and is then subjected to a pressurization of 0.98 MPa at a high temperature of 120-160° C. for ten minutes, thus temporarily crimping the metal base 11 and the insulating resin layer 13. Subsequently, the thermoelectric module 10a is laminated on the insulating resin layer 13 and is then subjected to a pressurization of 2.94 MPa at a high temperature of 170° C. for sixty minutes, thus bonding the thermoelectric module 10a, the metal base 11, and the insulating resin layer 13 together. As the insulating resin layer 13, it is possible to use an adhesive synthetic resin having an electrically insulating property, such as a polyimide resin and epoxy resin, instead of the aforementioned synthetic resin sheet. Preferably, the polyimide resin or epoxy resin additionally includes fillers composed of alumina powder, aluminum nitride powder, magnesium oxide powder, and silicon carbide powder so as to improve in thermal conductivity.

Next, the solder 18 composed of the In solder (melting point: 156° C.), BiSn solder (melting point: 157° C.), or SnInAg solder (melting point: 180-190° C.) is applied to the periphery of the metal base 11; then, the rectangular metal frame 12 composed of an iron-nickel-cobalt alloy (e.g. the Kovar (registered trademark) with a thermal expansion coefficient (or a linear expansion coefficient α) of 5.7×10⁻⁶/K through 6.5×10⁻⁶/K) is disposed on the solder 18. Subsequently, the solder 18 is heated to melt so as to bond the metal frame 12 to the metal base 11 via the solder 18, thus completing the production of the package 10 including the thermoelectric module 10a.

It is essential that the solder 18 used for bonding the metal base 11 and the metal frame 12 have a low melting point solder such as the In solder (melting point: 156° C.), BiSn solder (melting point: 157° C.), and SnInAg solder (melting point: 180-190° C.), which is lower than the solders 16a and 16b used for forming the thermoelectric module 10a such as the SnSb solder (melting point: 235° C.), SnAu solder (melting point: 280° C.), and SnAgCu solder (melting point: 220° C.).

The above description refers to the polyimide resin and epoxy resin as the synthetic resin material; but this is not a restriction. It is possible to use other materials (other than the polyimide resin and epoxy resin) such as the aramid resin and bismaleimide-triazine (BT) resin.

The above description also refers to the alumina powder, aluminum nitride powder, magnesium oxide powder, and silicon carbide powder as the filler material; but this is not a restriction. It is possible to use other high thermal conductivity materials such as the carbon powder and silicon nitride powder. The filler material is not necessarily limited to a single type of material; hence, it is possible to blend two or more types of filler materials. Furthermore, it is possible to adopt any shaping of fillers such as spherical shapes and acicular shapes or to blend different shapes of fillers.

Lastly, the present invention is not necessarily limited to the present embodiment and examples, which can be modified in various ways within the scope of the invention as defined by the appended claims.

What is claimed is:

1. A package adapted to a thermoelectric module including a plurality of thermoelectric elements sandwiched between an upper electrode and a lower electrode, comprising:
a metal base constituted of a metal plate composed of copper, aluminum, silver, or alloy;
a metal frame which is attached to a periphery of the metal base; and
an insulating resin layer having good thermal conductivity, via which the thermoelectric module is attached onto the metal base and circumscribed by the metal frame,
wherein the metal frame is attached to the metal base via a low melting point solder whose melting point is lower than that of a solder used for bonding the thermoelectric elements with the upper electrode and the lower electrode in the thermoelectric module.

2. The package according to claim 1 further comprising a secondary metal plate composed of copper, aluminum, silver, or alloy, which is attached onto the upper electrode of the thermoelectric module via a secondary insulating resin layer having a good thermal conductivity.

3. The package according to claim 1, wherein a trench or a recess is formed in the metal plate to engage with the lower portion of the metal frame.

4. The package according to claim 1, wherein the surface of the metal base is coated with a metal coating layer having good corrosion resistance and good soldering wettability.

5. The package according to claim 4, wherein the metal coating layer is composed of a nickel plating layer or composed of a gold plating layer deposited on the nickel plating layer.

6. The package according to claim 1, wherein the metal frame is composed of an iron-nickel-cobalt alloy or a stainless steel alloy.

7. The package according to claim 1, wherein the insulating resin layer is an insulating resin sheet including fillers having good thermal conductivity.

8. The package according to claim 7, wherein the fillers are composed of an alumina powder, an aluminum nitride powder, a magnesium oxide powder, or a silicon carbide powder.

9. The package according to claim 7, wherein the insulating resin sheet is composed of a polyimide resin or an epoxy resin.

10. A manufacturing method of a package adapted to a thermoelectric module including a plurality of thermoelectric elements sandwiched between a lower electrode and an upper electrode, in which the package is constituted of a metal base and a metal frame attached to the periphery of the metal base so that the thermoelectric module is attached onto the metal base and circumscribed by the metal frame, said manufacturing method comprising:
bonding the lower electrode of the thermoelectric module onto the metal base, which is a metal plate composed of copper, aluminum, silver, or alloy, via an insulating resin layer having good thermal conductivity;
bonding the plurality of thermoelectric elements with the lower electrode and the upper electrode via a first solder, wherein the plurality of thermoelectric elements is aligned on the lower electrode and below the upper electrode joining to a heat-resistant resin film;
extracting the heat-resistant resin film from the upper electrode; and
bonding the metal frame onto the periphery of the metal base via a second solder whose melting point is lower than a melting point of the first solder.

11. A manufacturing method of a package adapted to a thermoelectric module including a plurality of thermoelectric elements sandwiched between a lower electrode and an upper electrode, in which the package is constituted of a metal base and a metal frame attached to the periphery of the metal base so that the thermoelectric module is attached onto the metal base and circumscribed by the metal frame, said manufacturing method comprising:
bonding the lower electrode of the thermoelectric module onto the metal base, which is a metal plate composed of copper, aluminum, silver, or alloy, via a first insulating resin layer having a good thermal conductivity;
bonding a secondary metal plate composed of copper, aluminum, silver, or alloy onto the upper electrode of the thermoelectric module via a second insulating resin layer having good thermal conductivity;
bonding the plurality of thermoelectric elements with the lower electrode and the upper electrode via a first solder, wherein the plurality of thermoelectric elements is aligned on the lower electrode and below the upper electrode joining to the second insulating resin layer; and
bonding the metal frame onto the periphery of the metal base via a second solder whose melting point is lower than a melting point of the first solder.

12. A manufacturing method of a package adapted to a thermoelectric module including a plurality of thermoelectric elements sandwiched between a lower electrode and an upper electrode, in which the package is constituted of a metal base and a metal frame attached to the periphery of the metal base so that the thermoelectric module is attached onto the metal base and circumscribed by the metal frame, said manufacturing method comprising:
bonding the lower electrode of the thermoelectric module with a lower heat-resistant resin film while bonding the upper electrode of the thermoelectric module with an upper heat-resistant resin film;
bonding the plurality of thermoelectric elements with the lower electrode and the upper electrode via a first solder, wherein the plurality of thermoelectric elements is aligned on the lower electrode joining to the lower heat-resistant resin film and below the upper electrode joining to the upper heat-resistant resin film;
extracting the upper heat-resistant resin film from the upper electrode while extracting the lower heat-resistant resin film from the lower electrode;
bonding the thermoelectric module onto the metal base, which is a metal plate composed of copper, aluminum, silver, or alloy, via an insulating resin layer having a good thermal conductivity; and
bonding the metal frame onto the periphery of the metal base via a second solder whose melting point is lower than a melting point of the first solder.
